(19) United States
(12) Patent Application Publication
(10) Pub. No.: US 2008/0259583 A1
(43) Pub. Date: Oct. 23, 2008

(54) Chip Module and Method for Producing a Chip Module

(76) Inventor: Manfred Rietzler, Marktoberdorf (DE)

Correspondence Address: PROSKAUER ROSE LLP, ONE INTERNATIONAL PLACE, BOSTON, MA, 02110, US

(21) Appl. No.: 12/066,741

(22) PCT Filed: Aug. 28, 2006
(86) PCT No.: PCT/DE06/01494

§ 371 Date: Mar. 13, 2008

(30) Foreign Application Priority Data
Sep. 15, 2005 (DE) 10 2005 044 216.1

(51) Int. Cl. H01L 21/56; H05K 7/02

(52) U.S. Cl. 361/807; 438/124; 257/E21.502

(57) ABSTRACT

The invention pertains to a chip module for producing contactless chip cards with a chip carrier that is provided with inner and outer contacts on a substrate, wherein the inner contacts are bonded to terminal areas of a chip unit arranged on the chip carrier and the outer contacts serve for being bonded to an antenna, and wherein the chip unit is accommodated in a sandwich-like fashion between the substrate and a fiber-reinforced cover layer such that the cover layer is connected to the substrate adjacent to at least two opposite lateral edges of the chip unit, as well as to a method for producing a chip module.

### RELATED APPLICATIONS

This application is the U.S. National stage of International Application No. PCT/DE2006/001494, filed on Aug. 28, 2006, published in German, which claims priority to German Patent Application No. 10 2005 044 216.1, filed Sep. 15, 2005. The entire teachings of the above applications are incorporated herein by reference.

### FIELD OF THE INVENTION

The present invention pertains to a chip module for producing contactless chip cards with a chip carrier that is provided with inner and outer contacts on a substrate, wherein the inner contacts are bonded to terminal areas of a chip unit arranged on the chip carrier and the outer contacts serve for being bonded to an antenna. The invention furthermore pertains to a method for producing such a chip module.

### BACKGROUND

Chip modules that are implemented in the card body of chip cards are subjected to particularly high stresses due to the frequently occurring bending loads to which the card is subjected when it is used. This applies all the more to chip modules used for producing contactless chip cards because chip modules of this type do not feature external terminal area arrangements that contribute to an overall reinforcement of the chip module. In order to still realize a sufficient reinforcement of the chip module that sufficiently protects the chip and the bonding between the chip and the chip carrier of the chip module from mechanical bending loads, it is known, for example, to provide the chip or the chip module with a sealing compound that envelopes the chip. However, since this sealing compound needs to have a sufficient mass in order to effectively protect the chip, the application of such a sealing compound is typically associated with a significant increase of the chip module thickness that, in turn, can lead to problems in the card production depending on the structure of the card body of the chip card.

### SUMMARY OF THE INVENTION

Consequently, the present invention is based on the objective of proposing a chip module and a method for producing a chip module, the rigidity of which is substantially increased and the thickness of which is only slightly larger than that of a non-protected chip module, i.e., a chip module without an additional reinforcing device.

This objective is respectively attained with a chip module with the characteristics of Claim 1 and a method for producing a chip module with the characteristics of Claim 8.

The inventive chip module for producing contactless chip cards features a chip carrier that is provided with inner and outer contacts on a substrate, wherein the inner contacts are bonded to terminal areas of a chip unit arranged on the chip carrier and the outer contacts serve for being bonded to an antenna. In the inventive chip module, the chip unit is accommodated in a sandwich-like fashion between the substrate and a fiber-reinforced cover layer such that the cover layer is connected to a chip surface, as well as to the substrate adjacent to at least two opposite lateral edges of the chip unit.

In the inventive chip module, the cover layer therefore produces a non-positive connection between the chip surface and substrate regions arranged adjacent to opposite lateral edges of the chip unit. Consequently, the cover layer forms a reinforcing bridge between substrate regions arranged adjacent to opposite lateral edges of the chip unit. In this case, the fiber reinforcement of the cover layer ensures the transmission of tensile stresses required for the non-positive connection.

According to one advantageous embodiment of the chip module, the cover layer is connected to the substrate along a periphery of the chip unit. This not only allows a uniaxial transmission of tensile stresses, but also a biaxial transmission of tensile stresses such that the cover layer is able to absorb tensile stresses caused by longitudinal bending and lateral bending of the card body.

If the cover layer is furthermore connected to a chip surface, the cover layer results in an additional reinforcement between the chip surface and the substrate regions arranged adjacent to lateral edges of the chip unit.

The connection between the cover layer and the substrate regions or the cover layer and the chip surface can be produced directly or with the aid of intermediately arranged additional materials that, depending on their function, may be composed of the materials of the cover layer or the substrate or of different materials. For example, a reinforcing or shock-absorbing peripheral ring may be arranged between the cover layer and the substrate regions. It would also be possible, for example, to arrange surface layers that absorb UV-radiation or IR-radiation or shocks between the cover layer and a chip surface and/or a chip surface and the substrate.

An additional protection of the chip unit from mechanical stresses can be realized if the connection between the chip unit and the cover layer and/or the substrate has a certain relative mobility, i.e., if this connection is realized in a “floating” fashion, for example, in the form of an elastic bonded connection.

In one particularly advantageous embodiment of the chip module, the chip unit is accommodated in a laminated connection between the substrate and the cover layer. The realization of the laminated connection between the substrate and the cover layer makes it possible to realize a particularly secure and large-surface connection between the substrate and the cover layer, as well as between the cover layer and the chip surface.

A reinforcing device that absorbs compressive stresses as well as tensile stresses can be realized if the cover layer is produced on the basis of epoxy resin.

A chip module with an encapsulation that envelopes the chip unit on all sides and features a chip carrier that is realized in a particularly rigid fashion in addition to the cover layer can be realized if the cover layer as well as the substrate are produced on the basis of epoxy resin, wherein the substrate may also be provided with a fiber-reinforced layer.

A particularly flat design of the chip module in conjunction with the reinforcing device that has a particularly flat design due to the use of the cover layer can be realized if the chip unit with its terminal areas is bonded against the inner contacts of the chip carrier, i.e., connected to the chip carrier in accordance with the so-called flip-chip method.

An additional reduction of the chip module thickness can be achieved if the chip unit has a thickness that is reduced in comparison with its standard thickness.

According to the inventive method for producing a chip module with a chip carrier that is provided with inner and outer contacts on a substrate and a chip unit bonded to the inner contacts, terminal areas of the chip unit are bonded to the inner contacts of the chip carrier in a first process step. Subsequently, a fiber-reinforced cover layer is applied onto the chip unit such that the chip unit is arranged in a sandwich-like fashion between the substrate and the cover layer. The cover layer is then connected to the substrate adjacent to at least two opposite lateral edges of the chip unit.

In addition, the cover layer can also be connected to a chip surface. This can be carried out in the same process step in which the connection between the cover layer and the substrate is produced.

As mentioned above, it is particularly advantageous if the connection between the cover layer and the substrate is produced by means of a laminating process. Moreover, a positive connection, in particular, between the chip surface and the cover layer can also be produced by means of a laminating process. According to an alternative embodiment, however, it is also possible to realize the connection between the cover layer and the chip surface in the form of a bonded connection so as to reduce the temperature stress of the chip unit, if so required.

It is particularly advantageous if a continuous connection between the cover layer and the substrate is produced along the periphery of the chip unit during the laminating process, namely because this results in an encapsulation of the chip unit that seals the chip unit on the substrate.

It is particularly advantageous if the laminating process is carried out by means of a die that defines the shape of the chip encapsulation because this makes it possible to adapt the chip encapsulation to the respective installation or integration situation of the chip module in the card body.

A particularly flat design of the chip unit can be realized if the bonding of the terminal areas of the chip unit to the inner contacts of the chip carrier is carried out such that the chip unit is bonded against the contacts of the chip carrier with its terminal areas that face the contacts of the chip carrier.

The small thickness of the chip module attained with the above-described flip-chip bonding of the chip unit on the substrate can be additionally reduced if the chip unit thickness is reduced by means of an abrasive material processing method subsequent to the bonding of the chip unit on the chip carrier and prior to the application of the cover layer onto the chip unit.

### BRIEF DESCRIPTION OF THE DRAWINGS

One preferred embodiment of the invention is described in greater detail below with reference to the figures.

The figures show:

FIG. 1, a chip module in the form of a cross-sectional representation and a side view;

FIG. 2, the chip module illustrated in FIG. 1 in the form of a side view according to the arrow II in FIG. 1;

FIG. 3, the chip module illustrated in FIG. 1 in the form of a top view;

FIG. 4, a chip carrier composite consisting of a plurality of interconnected chip carriers with chip units bonded thereon, namely in the form of a top view;

FIG. 5, the chip carrier composite illustrated in FIG. 4 with a cover layer arranged above the chip units in the form of a side view;

FIG. 6, the chip carrier composite illustrated in FIG. 5 with the cover layer arranged above the chip units during the laminating process, and

FIG. 7, a chip module composite created by means of the laminating process before its separation into individual chip modules.

### DETAILED DESCRIPTION

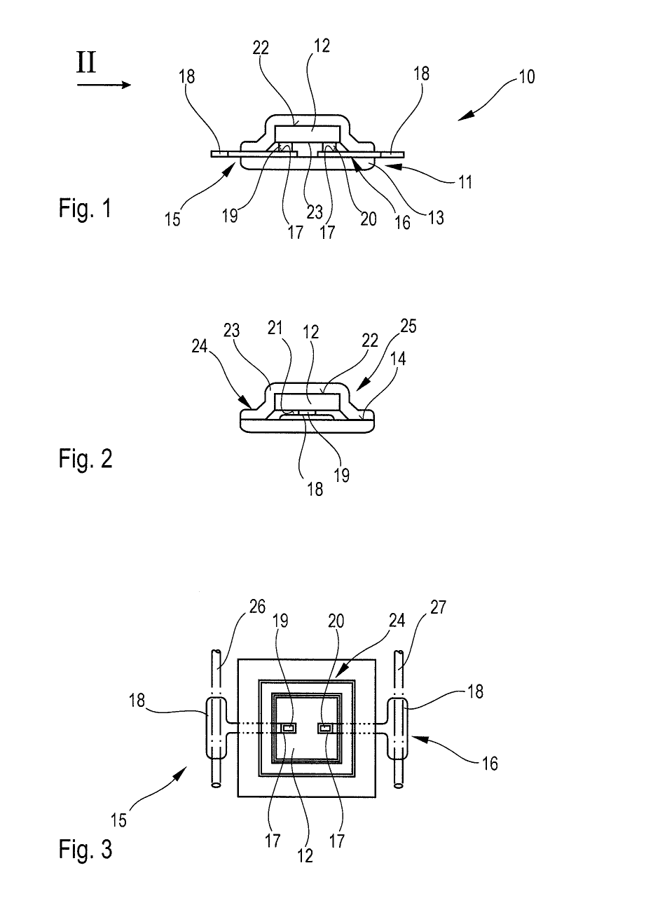

FIG. 1 shows a chip module 10 with a chip unit 12 arranged on a chip carrier 11. In this case, the chip carrier 11 features an epoxy resin substrate 13 that, in accordance with the pertinent technical terminology, is also referred to as a “FR4-substrate.” FIG. 1 in conjunction with FIGS. 2 and 3 furthermore shows that the upper side 14 of the substrate 13 which faces the chip unit 12 is provided with a terminal area arrangement that comprises two terminal leads 15 and 16. The terminal leads 15, 16 respectively feature an inner contact end 17 and an outer contact end 18. The inner contact ends 17 are bonded to the terminal areas of the chip unit 12 that are realized in the form of bumps 19, 20 in this case.

A cover layer 23 is situated on the rear side 22 of the chip unit 12 that lies opposite of the front side 21 of the chip unit 12 being provided with the bumps 19, 20, wherein said cover layer clings to the outside contour of the chip unit 12 and is connected to the upper side 14 of the substrate 13 along a periphery 24 of the chip unit 12 by means of a laminated connection 35. Due to its design in the form of an encapsulation of the chip unit 12 and the laminated connection 35 with the substrate 13 along the periphery 24 of the chip unit 12, the cover layer 23 forms a reinforcing device that accommodates the chip unit 12 and increases the overall rigidity of the chip module 10.

According to FIG. 3, only the outer contact ends 18 of the terminal leads 15, 16 that serve for being bonded to the merely indicated contact ends 26, 27 of an antenna in FIG. 3 protrude laterally from an encapsulation 25 that seals the chip unit 12 to the substrate 13.

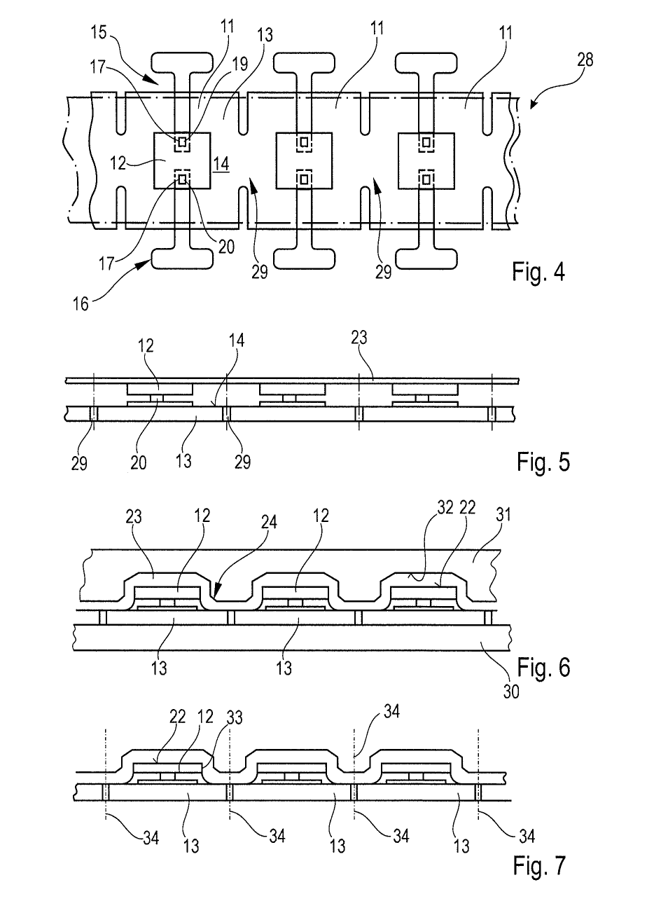

A method for producing the chip module 10 illustrated in FIGS. 1 to 3 is described below with reference to FIGS. 4 to 7.

According to FIG. 4, the method can be carried out based on a chip carrier composite 28 that comprises a plurality of chip carriers 11 illustrated in FIGS. 1 to 3 in an interconnected arrangement. The chip carrier composite 28 can be separated into individual chip carriers 11 at separating points defined by connecting webs 29. The combination of FIGS. 4 and 5 clearly shows that chip units 12 are already bonded by means of their bumps 19, 20 to the inner contact ends 17 of the terminal leads 15, 16 arranged on the upper side 14 of the substrate 13 in the processing stage shown. The cover layer 23 is situated on the rear sides 22 of the chip units 12 and in the present case consists of a fiber-reinforced epoxy material that represents a widely used semi-finished product for the production of lightweight constructions—and is frequently referred to as a glass fiber mat or glass fiber prepreg.

In this case, the epoxy resin material contained in the cover layer 23 forms, as is well known, a thermosetting support matrix for the glass fibers embedded in the epoxy resin mass which can be laminated and allows the transmission of tensile stresses. However, it would also be possible, in principle, to utilize other composite fiber materials with comparable characteristics for the cover layer 23.

After the cover layer 23 is arranged on the rear sides 22 of the chip units 12, a laminating process takes place in which the layered arrangement illustrated in FIG. 5 which comprises the chip carrier composite 28 and the cover layer 23 is arranged between a lower laminating plate 30 and an upper laminating plate 31. The laminating plate 31 is realized in the form of a die with a plurality of molding cavities 32, the arrangement of which corresponds to that of the chip units 12, wherein said cavities are dimensioned and shaped such that the cover layer 23 clings to the rear sides of the chip units 12 when the laminating plates 30, 31 are pressed together as shown in FIG. 6 and the cover layer 23 is simultaneously pressed against the substrate 13 of the chip carrier composite 28 in the peripheral regions 24 of the chip units 12. In the configuration shown in FIG. 6, at least the laminating plate 31 is subjected to temperature such that the dimensionally stable laminated connection 35 illustrated in FIG. 7 is produced between the cover layer 23 and the substrates 13 of the chip carrier composite 28 in the peripheral regions 24 of the chip units 12. The connection of the cover layer 23 to the chip units 12 is produced such that it positively accommodates the chip units 12 in the region of their rear sides 22 and outer sides 33.

Based on the configuration illustrated in FIG. 7, the only remaining step in the production of the chip modules 10 illustrated in FIGS. 1 to 3 is their separation by means of a punching or cutting process, in which the connecting webs 29 are severed at the separating points 34 shown in FIG. 7.

1. A chip module for producing contactless chip cards comprising:
a chip carrier having inner and outer contacts on a substrate, the inner contacts being bonded to terminal areas of a chip unit arranged on the chip carrier and the outer contacts being arranged for bonding to an antenna,
the chip unit being arranged between the substrate and a fiber-reinforced cover layer such that the cover layer is connected to the substrate adjacent to at least two opposite lateral edges of the chip unit.

2. The chip module according to claim 1, characterized in that wherein the cover layer is connected to the substrate along a periphery of the chip unit.

3. The chip module according to claim 1, characterized in that wherein the cover layer is connected to a chip surface.

4. The chip module according to claim 1, wherein the chip unit is connected to the substrate or to the cover layer with a certain relative mobility.

5. The chip module according to claim 1, wherein the chip unit is arranged in a laminated connection between the substrate and the cover layer.

6. The chip module according to claim 5, characterized in that wherein the cover layer is produced based on an epoxy resin.

7. The chip module according to claim 5, characterized in that wherein the cover layer and the substrate are produced based on an epoxy resin.

8. The chip module according to claim 1, wherein the terminal areas of the chip unit are bonded against the inner contacts of the chip carrier.

9. The chip module according to claim 8, characterized in that wherein the chip unit has a reduced thickness.

10. A method for producing a chip module with a chip carrier having inner and outer contacts on a substrate and a chip unit bonded to the inner contacts, the method further comprising:
bonding terminal areas of the chip unit to the inner contacts of the chip carrier;
applying a fiber-reinforced cover layer onto the chip unit such that the chip unit is arranged between the substrate and the cover layer; and
connecting the cover layer to the substrate adjacent to at least two opposite lateral edges of the chip unit.

11. The method according to claim 10, further comprising connecting the cover layer to a chip surface.

12. The method according to claim 10, characterized in that further comprising producing the connection between the cover layer and the substrate by a laminating process.

13. The method according to one of claims 10, further comprising:
producing the connection between the cover layer and the chip surface by a laminating process; and
producing the connection between the cover layer and the substrate by the laminating process.

14. The method according to one of claims 12, further comprising producing a continuous connection between the cover layer and the substrate along the periphery of the chip unit during the laminating process.

15. The method according to one of claims 12, wherein the laminating process uses a die to form a chip encapsulation with a defined shape.

16. The method according to one of claims 10, further comprising:
bonding the terminal areas of the chip unit to the inner contacts of the chip carrier such that the terminal areas of the chip unit face and are bonded against the contacts of the chip carrier.

17. The method according to claim 16, further comprising:
reducing the thickness of the chip unit using an abrasive material processing method subsequent to bonding the chip unit to the chip carrier and prior to application of the cover layer onto the chip unit.

18. The chip module according to claim 1 wherein the connection of the cover layer to the substrate is carried out having at least one intermediate material being arranged between the cover layer and the substrate.

19. The chip module according to claim 18, wherein the intermediate material is formed as a peripheral ring.

20. The chip module according to claim 3, wherein the connection of the cover layer to the chip surface is carried out having al least one intermediate material being arranged between the cover layer and the chip surface.
